(19) United States
(12) Patent Application Publication
(10) Pub. No.: US 2024/0431218 A1
(43) Pub. Date: Dec. 26, 2024

(54) SWITCH BASED ON A PHASE-CHANGE MATERIAL

(71) Applicant: Commissariat à l'Énergie Atomique et aux Énergies Alternatives, Paris (FR)

(72) Inventor: Ismaël Charlet, Grenoble (FR)

(73) Assignee: Commissariat à l'Énergie Atomique et aux Énergies Alternatives, Paris (FR)

(21) Appl. No.: 18/739,748

(22) Filed: Jun. 11, 2024

(30) Foreign Application Priority Data
Jun. 20, 2023 (FR) 2306345

(51) Int. Cl. H10N 70/20; G02B 6/12

(52) U.S. Cl. CPC H10N 70/231; G02B 6/12004

(57) ABSTRACT

A switch based on a phase-change material including: a region made of said phase-change material coupling first and second conduction electrodes of the switch; and an optical coupler of a laser signal for activating the switch, located in front of a surface of the region made of said phase-change material.

### TECHNICAL FIELD

The present disclosure generally concerns electronic devices. The present disclosure more particularly concerns switches based on a phase-change material, capable of alternating between a crystalline, electrically-conductive phase and an amorphous, electrically-insulating phase.

### PRIOR ART

Various applications take advantage of switches based on a phase-change material to allow or to prevent the flowing of an electric current in a circuit. Such switches can in particular be used in radio frequency communication applications, for example to switch an antenna between transmit and receive modes, to activate a filter corresponding to a frequency band, etc.

Existing phase-change switches however suffer from various disadvantages.

### SUMMARY OF THE INVENTION

There exists a need to improve existing switches based on a phase-change material.

For this purpose, an embodiment provides a switch based on a phase-change material comprising:
a region made of said phase-change material coupling first and second conduction electrodes of the switch; and
an optical coupler of a laser signal for activating the switch, located in front of a surface of the region made of said phase-change material.

According to an embodiment, the optical coupler comprises first and second waveguides stacked in front of said surface, the second waveguide being interposed between the first waveguide and the region made of said phase-change material.

According to an embodiment, the first and second waveguides each comprise a central region made of a first material surrounded by a peripheral region made of a second material having an optical index lower than that of the first material.

According to an embodiment, the central regions of the first and second waveguides are stacked, in front of each other, and have a same pattern vertically in line with the region made of said phase-change material.

According to an embodiment, the central regions of the first and second waveguides do not have a same pattern out of line with the region made of said phase-change material.

According to an embodiment, the central region of the first waveguide has a geometry and dimensions substantially identical to those of the central region of the second waveguide. According to an embodiment, the optical coupler is an adiabatic coupler.

According to an embodiment, the first and second waveguides respectively comprise output and input surfaces, each having, in top view, a tapered shape.

According to an embodiment, the laser signal is confined and guided mainly by the first waveguide, at the input of the optical coupler, and mainly by the second waveguide, at the output of the optical coupler.

According to an embodiment, the first and second conduction electrodes form part of an antenna element of a cell of a transmitarray or of a reflectarray.

An embodiment provides a cell of a transmitarray or of a reflectarray comprising at least one switch such as described.

An embodiment provides a transmitarray or a reflectarray, comprising:
a plurality of cells such as described;
one or a plurality of laser sources; and
a circuit for controlling the laser source(s).

According to an embodiment, each laser source forms part of a same chip as each switch with which it is associated.

An embodiment provides an antenna comprising a transmitarray or a reflectarray such as described and at least one source configured to irradiate a surface of the array.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A and FIG. 1B are simplified and partial views, respectively a top view and a cross-section view along plane BB of FIG. 1A, illustrating an example of a switch based on a phase-change material;

FIG. 2A, FIG. 2B, and FIG. 2C are simplified and partial views, respectively a top view, a cross-section view along plane BB of FIG. 2A, and a cross-section view along plane CC of FIG. 2A, illustrating an example of a switch based on a phase-change material according to an embodiment;

FIG. 3 is a simplified and partial side view of an example of a transmitarray antenna of the type to which apply, as an example, the described embodiments;

FIG. 4 is a simplified and partial isometric view of an elementary cell of the transmitarray of the antenna of FIG. 3, according to an embodiment; and

FIG. 5 is a simplified and partial top view illustrating an example of a switch based on a phase-change material according to an embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the circuits for controlling the switches based on a phase-change material and the applications in which such switches can be provided have not been detailed, the described embodiments and variants being compatible with usual circuits for controlling switches based on a phase-change material and with usual applications implementing switches based on a phase-change material.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

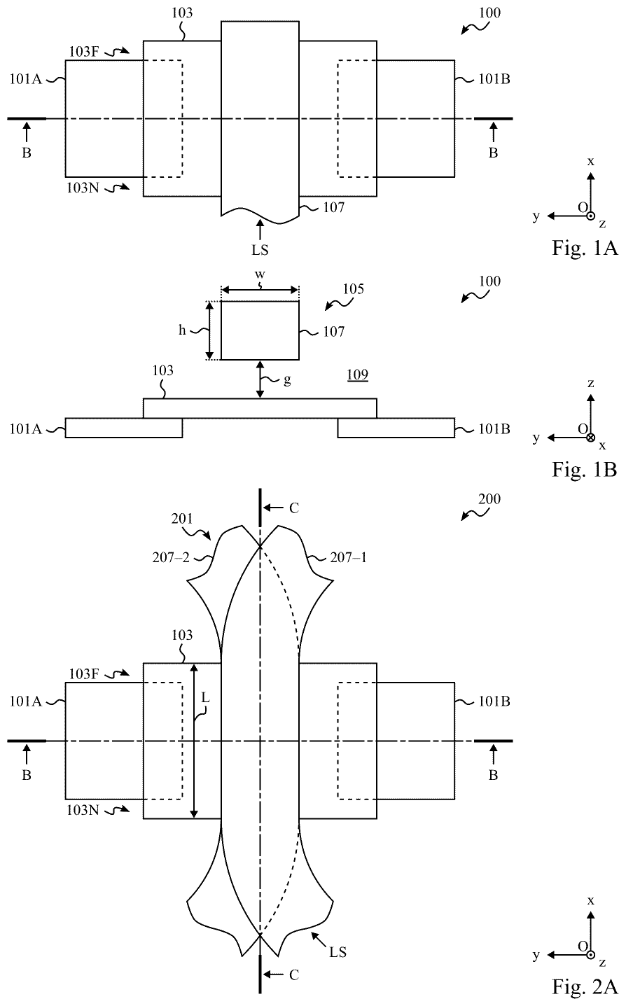

FIG. 1A and FIG. 1B are simplified and partial views, respectively a top view and a cross-section view along plane BB of FIG. 1A, illustrating an example of a switch 100 based on a phase-change material. In the shown example, plane BB of FIG. 1A is a vertical plane parallel to a conduction direction of switch 100.

In FIGS. 1A and 1B, the conduction direction of switch 100 is parallel to a horizontal axis Oy, and plane BB is parallel to a vertical plane Oyz orthogonal to an axis Ox.

In the shown example, switch 100 comprises conduction electrodes 101A and 101B. The conduction electrodes 101A and 101B of switch 100 are for example intended to be connected to a radio frequency communication circuit, not detailed in the drawings. Conduction electrodes 101A and 101B are made of an electrically-conductive material, for example a metal, for example copper or aluminum, or of a metal alloy. Further, conduction electrodes 101A and 101B may have a monolayer or multi-layer structure.

Although this has not been detailed in FIGS. 1A and 1B so as not to overload the drawing, the conduction electrodes 101A and 101B of switch 100 are for example located on top of and in contact with an upper surface of an electrically-insulating layer, for example made of silicon dioxide (SiO₂), coating a substrate. As an example, the substrate is in this case a wafer or a piece of wafer made of a semiconductor material, for example silicon.

In the illustrated example, switch 100 further comprises a region 103 made of a phase-change material coupling conduction electrodes 101A and 101B. Although this has not been detailed in the drawings, region 103 of phase-change material for example coats an upper surface of another electrically-insulating layer, for example made of silicon dioxide, laterally extending between electrodes 101A and 101B, the electrically-insulating layer being flush with, for example, the upper surfaces of electrodes 101A and 101B. In the shown example, region 103 of phase-change material extends on top of and in contact with a portion of the upper surface of each conduction electrode 101A, 101B. As an example, region 103 of phase-change material has a thickness in the order of 100 nm.

As an example, region 103 of switch 100 is made of a “chalcogenide” material, that is, a material or an alloy comprising at least one chalcogen element, for example a material from the family of germanium telluride (GeTe), antimony telluride (SbTe), or germanium-antimony-telluride (GeSbTe, commonly designated with the acronym “GST”). As a variant, region 103 is made of vanadium dioxide (VO₂).

Generally, phase-change materials are materials capable of alternating, under the effect of a temperature variation, between a crystalline phase and an amorphous phase, the amorphous phase having a higher electric resistance than the crystalline phase. In the case of switch 100, advantage is taken of this phenomenon to obtain a blocked state, preventing the flowing of a current between conduction electrodes 101A and 101B, when the material of region 103 located between the conduction electrodes is in the amorphous phase, and a conductive state, allowing the flowing of current between conduction electrodes 101A and 101B, when the material of region 103 is in the crystalline phase.

In the shown example, switch 100 further comprises a waveguide 105 located in front of region 103 of phase-change material and extending laterally along a main direction substantially orthogonal to the conduction direction of switch 100. In FIGS. 1A and 1B, the waveguide 105 of switch 100 extends parallel to axis Ox. Waveguide 105 has, for example, a first end located in front of an upper surface of region 103 of phase-change material and a second end, opposite to the first end, intended to be illuminated by a laser source LS. As an example, the radiation emitted by laser source LS has a transverse magnetic (TM) polarization or a transverse electric (TE) polarization.

In the illustrated example, waveguide 105 comprises a central region 107, or core, surrounded by an electrically-insulating peripheral region 109. In the illustrated example, the central region 107 of waveguide 105 extends parallel to axis Ox. The central region 107 and the peripheral region 109 of waveguide 105 are made of materials selected to obtain an optical index contrast enabling to confine and to guide an optical mode of interest emitted by laser source LS. As an example, the material of the central region 107 of waveguide 105 has an optical index higher than that of the peripheral region 109. For example, the central region 107 of waveguide 105 is made of silicon nitride and the peripheral region 109 is made of silicon dioxide.

Plane BB of FIG. 1A is substantially orthogonal to a direction of propagation of the laser radiation in waveguide 105. The direction of propagation of the laser radiation in waveguide 105 is, in the illustrated example, parallel to axis Ox. In the shown example, the peripheral region 109 of waveguide 105 covers the surfaces of central region 107 parallel to the laser radiation propagation direction (the lateral, lower, and upper surfaces of the central region 107 of waveguide 105 parallel to axis Ox, in FIGS. 1A and 1B). In this example, a portion of the peripheral region 109 of waveguide 105 extends vertically, along vertical axis Oz orthogonal to horizontal axes Ox and Oy, from a surface of central region 107 located in front of region 103 of phase-change material (the lower surface of the central region 107 of waveguide 105, in the orientation of FIG. 1B) to a surface of region 103 of phase-change material opposite to conduction electrodes 101A and 101B (the upper surface of region 103 of phase-change material, in the orientation of FIG. 1B).

In the shown example, central region 107 has, in cross-section view along the plane BB orthogonal to the direction of propagation of the laser radiation in waveguide 105, a substantially rectangular cross-section. As an example, central region 107 has, in cross-section along plane BB, a width w (along axis Ox) equal to approximately 300 nm and a height h (along axis Oz) equal to approximately 350 nm. Further, the central region 107 of waveguide 105 is separated from region 103 of phase-change material by a distance g. In this example, distance g is equivalent to a thickness of the portion of peripheral region 109 interposed between the central region 107 of waveguide 105 and region 103 of phase-change material. As an example, distance g is equal to approximately 300 nm.

Waveguide 105 is for example of monomode type, that is, it is adapted to confining and guiding a single optical mode for each polarization type. Waveguide 105 is for example more specifically adapted to confining and guiding a single optical mode selected from a zero-order transverse electric mode (TE0), parallel to axis Oy, and a zero-order transverse magnetic mode (TM0), parallel to axis Oz. Since modes TE0 and TM0 are orthogonal, they cannot couple to each other in waveguide 105. The selection of the mode confined and guided by waveguide 105, between mode TE0 and mode TM0, is determined by the polarization of laser source LS. Thus, in a case where laser source LS emits a radiation having a transverse magnetic polarization TM, waveguide 105 is adapted to confining and guiding the zero-order transverse magnetic mode TM0 only.

On the side of its end intended to be illuminated by laser source LS, waveguide 105 comprises, for example, an input coupling element, also called input surface of waveguide 105. On the side of its end located in front of region 103 of phase-change material, waveguide 105 may further comprise an output coupling element, also called output surface of waveguide 105. The input coupling element may have a structure, such as a diffraction grating having a Bragg structure or any other coupling structure, enabling to capture the radiation emitted by laser source and to propagate this radiation to the output surface.

Further, the output surface of waveguide 105 may have a structure enabling to re-emit the radiation propagated from the input surface to region 103 of phase-change material. Although this has not been detailed in FIGS. 1A and 1B, the output surface of waveguide 105 may have a structure identical or similar to that of its input surface.

Generally, the input and output surfaces of waveguide 105 respectively enable, in the shown example, to receive and to transmit a radiation along a direction orthogonal to the propagation direction of the radiation within waveguide 105, for example a direction parallel to axis Oz. As a variant, at least one surface, among the input and output surfaces of waveguide 105, may have a structure respectively enabling to receive or to transmit a radiation along a direction parallel to the direction of propagation of the radiation within waveguide 105 (parallel to axis Ox, in this example).

To switch switch 100 from the off state to the on state, for example, region 103 is heated, by means of laser source LS, via waveguide 105, to a temperature T1 and for a time period d1. Temperature T1 and time period d1 are selected to cause a phase change of the material of region 103 from the amorphous phase to the crystalline phase. As an example, temperature T1 is higher than a crystallization temperature and lower than a melting temperature of the phase-change material, and time period d1 is in the range from 10 to 100 ns.

Conversely, to switch switch 100 from the on state to the off state, region 103 is for example heated, by means of laser source LS, via waveguide 105, to a temperature T2, higher than temperature T1, and for a time period d2, shorter than time period d1. Temperature T2 and time period d2 are selected to cause a phase change of the material of region 103 from the crystalline phase to the amorphous phase. As an example, temperature T2 is higher than the melting temperature of the phase-change material, and time period d2 is in the order of 10 ns.

As an example, in a case where laser source LS is based on krypton fluoride, a radiation having a wavelength equal to approximately 248 nm is emitted by laser source LS, for example in the form of pulses, to cause transitions of the material of region 103 between the amorphous and crystalline phases. A pulse having a fluence in the order of 85 mJ.cm⁻² is for example used to obtain a transition of the material of region 103 from the amorphous phase to the crystalline phase. Further, another pulse having a fluence in the order of 185 mJ.cm⁻² is for example used to obtain a transition of the material of region 103 from the crystalline phase to the amorphous phase.

A disadvantage of switch 100 lies in the fact that the laser radiation emitted by source LS is not homogeneously absorbed in region 103 of phase-change material along the direction of propagation of the radiation in waveguide 105 (along axis Ox, in this example). In the example of switch 100, the laser radiation is mainly absorbed by a first portion 103N of region 103 of phase-change material close to laser source LS, the absorption of the laser radiation being lighter in a second portion 103F of region 103 of phase-change material, opposite to first portion 103N, more distant from laser source LS than portion 103N. The optical absorption of the laser radiation by region 103 of phase-change material more specifically follows a decreasing exponential curve from portion 103N of region 103 to portion 103F.

Thus, during a phase of activation of switch 100, the optical power absorbed by the second portion 103F of region 103 may turn out being insufficient to cause a phase change of the material in portion 103F. In the case where it is desired to switch switch 100 from the on state to the off state, this may prevent the second portion 103F of region 103 from changing phase from the crystalline phase to the amorphous phase, thus undesirably allowing the flowing of a leakage current between the conduction electrodes 101A and 101B of switch 100.

The inventor has found out that the phenomenon originates from the fact that the transverse magnetic mode TM of the laser signal for activating switch 100 confined and guided by waveguide 105 is strongly absorbed by the phase-change material of region 103, thus resulting in a heating of portion 103N much greater than that observed in portion 103F. To overcome this problem, it could have been devised to modify the geometry of waveguide 105 to confine and guide only the transverse electric mode TE, which is more lightly absorbed by the phase-change material of region 103 than the transverse magnetic mode TM. For example, the transverse magnetic mode TM exhibits losses, due to absorption by the phase-change material of region 103, in the order of 2,500 dB.cm⁻¹, to be compared with approximately 500 dB.cm⁻¹ for the transverse electric mode TE. However, for equivalent laser power values, this would not enable to obtain a sufficient heating of region 103 to cause a phase change. More generally, in transverse electric mode TE as well as in transverse magnetic mode TM, the optical absorption follows a law of decreasing exponential type for this guide configuration. However, it would be preferable for the absorption to follow a linear law to enable to modify the state of the phase-change material of region 103.

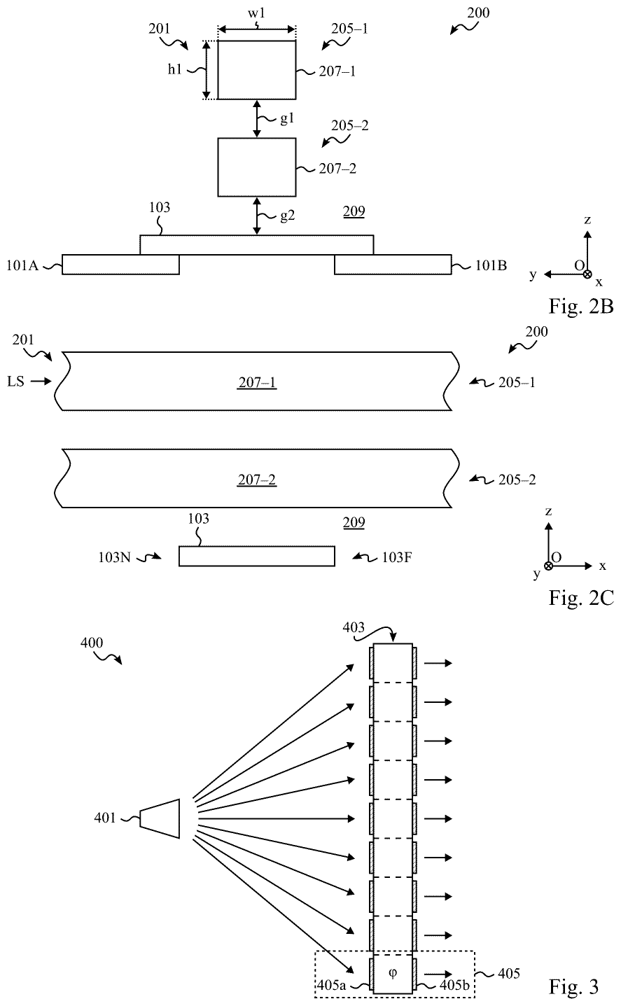

FIG. 2A, FIG. 2B, and FIG. 2C are simplified and partial views, respectively a top view, a cross-section view along plane BB of FIG. 2A, and a cross-section view along plane CC of FIG. 2A, illustrating an example of a switch 200 based on a phase-change material according to an embodiment.

The switch 200 of FIGS. 2A, 2B, and 2C comprises elements in common with the switch 100 of FIGS. 1A and 1B. These common elements will not be detailed again hereafter. The switch 200 of FIGS. 2A, 2B, and 2C differs from the switch 100 of FIGS. 1A and 1B in that switch 200 comprises an optical coupler 201. In this example, optical coupler 201 comprises two stacked waveguides 205-1 and 205-2 in front of region 103 of phase-change material.

In the illustrated example, waveguide 205-2 is interposed between waveguide 205-1 and region 103 of phase-change material. In this example, waveguide 205-1, the most distant from region 103 of phase-change material, is intended to receive the laser signal for activating switch 200 from source LS, and waveguide 205-2, closer to region 103 of phase-change material than waveguide 205-1, is intended to be optically coupled, by an evanescent field, to waveguide 205-1. As an example, waveguides 205-1 and 205-2 form an optical coupler 201 of directional type.

Referring to the orientation of FIGS. 2B and 2C, waveguides 205-1 and 205-2 will sometimes, in the rest of the disclosure, be respectively designated with the qualifiers “upper” and “lower”.

In this example, optical coupler 201 is designed so that the signal is, at the input of optical coupler 201, that is, in the vicinity of portion 103N of region 103, confined and guided mainly in upper waveguide 205-1 and, at the output of optical coupler 201, that is, in the vicinity of portion 103F of region 103, confined and guided mainly in lower waveguide 205-2. For example, waveguides 205-1 and 205-2 each confine and guide the transverse magnetic mode TM of the laser signal for activating switch 200 emitted by source LS. As an example, the transverse magnetic mode TM exhibits losses, due to the absorption by the phase-change material of region 103, in the order of 500 dB.cm⁻¹ for upper waveguide 205-1, to be compared with approximately 2,500 dB.cm⁻¹ for lower waveguide 205-2. By injecting the laser signal for controlling switch 200 into upper waveguide 205-1, coupled to lower waveguide 205-2 vertically in line with region 103 of phase-change material, the optical power is better distributed between portion 103N of region 103 of phase-change material, the closest to laser source LS, and portion 103F of region 103, the most distant from laser source LS. In this example, the radiation emitted by laser source LS has a transverse magnetic polarization TM.

In the shown example, each waveguide 205-1, 205-2 has, for example, a structure identical or similar to that of the waveguide 105 previously described in relation with FIGS. 1A and 1B. In the illustrated example, each waveguide 205-1, 205-2 comprises a central region 207-1, 207-2, or core, surrounded by an electrically-insulating peripheral region 209. The central region 207-1, 207-2 and the peripheral region 209 of each waveguide 205-1, 205-2 are made of materials selected to obtain a optical index contrast enabling to confine and to guide the optical mode of interest emitted by laser source LS. The material of the central region 207-1, 207-2 of each waveguide 205-1, 205-2 for example has an optical index higher than that of peripheral region 209. As an example, the central region 207-1, 207-2 of each waveguide 205-1, 205-2 is made of silicon nitride and the peripheral region 209 is made of silicon dioxide.

In the illustrated example, the central regions 207-1 and 207-2 of waveguides 205-1 and 205-2 are stacked, in front of each other, and have the same pattern vertically in line with region 103. However, in this example, regions 207-1, 207-2 are not located in front of each other and/or do not have a same pattern out of line with region 103 of phase-change material. This enables to ensure that the optical coupling between waveguides 205-1 and 205-2 mainly takes place in front of region 103. This further enables to limit optical reflections due to a sudden or abrupt change of optical index, which would for example be observed in a case where region 207-2 of lower waveguide 205-2 would be abruptly interrupted vertically in line with region 207-1 of upper waveguide 205-1.

The plane BB of FIG. 2A is substantially orthogonal to a propagation direction of the laser radiation in waveguides 205-1 and 205-2 in front of region 103 (orthogonal to axis Ox and parallel to plane Oyz, in the illustrated example). In the shown example, vertically in line with region 103 of phase-change material, the peripheral region 209 of waveguides 205-1 and 205-2 coats the surfaces of central regions 207-1 and 207-2 parallel to the propagation direction of the laser radiation (the lateral, lower, and upper surfaces of the central regions 207-1 and 207-2 of waveguides 205-1 and 205-2 parallel to axis Ox, in the orientation of FIGS. 2A, 2B, and 2C). In this example, a portion of the peripheral region 209 of waveguides 205-1 and 205-2 extends vertically, along axis Oz, from a surface of central region 207-1 located in front of lower waveguide 205-2 (the lower surface of the central region 207-1 of upper waveguide 205-1, in the orientation of FIG. 2B) to a surface of the central region 207-2 of lower waveguide 205-2 opposite to region 103 of phase-change material (the upper surface of the central region 207-2 of lower waveguide 205-2, in the orientation of FIG. 2B). Further, another portion of the peripheral region 209 of waveguides 205-1 and 205-2 extends vertically, along axis Oz, from a surface of central region 207-2 located in front of region 103 of phase-change material (the lower surface of the central region 207-2 of lower waveguide 205-2, in the orientation of FIG. 2B) to a surface of region 103 of phase-change material opposite to conduction electrodes 101A and 101B (the upper surface of region 103 of phase-change material, in the orientation of FIG. 2B).

In the shown example, central regions 207-1 and 207-2 each have, in cross-section along plane BB, a substantially rectangular cross-section. As an example, the central region 207-1 of upper waveguide 205-1 has a cross-section having a shape and dimensions identical, to within manufacturing dispersions, to those of the central region 207-2 of lower waveguide 205-2. More specifically, in the orientation of FIG. 2B, the central region 207-1, 207-2 of each waveguide 205-1, 205-2 has a same width w1, along axis Ox, and a same height h1, along axis Oz. This example is however not limiting, and the central region 207-2 of lower waveguide 205-2 may, as a variant, have a cross-section having a shape and dimensions different from those of the cross-section of the central region 207-1 of upper waveguide 205-1.

Further, the central region 207-1 of upper waveguide 205-1 is separated from the central region 207-2 of lower waveguide 205-2 by a distance g1. In this example, distance g1 is equivalent to a thickness of the portion of peripheral region 209 interposed between the central region 207-1 of waveguide 205-1 and the central region 207-2 of waveguide 205-2. Further, the central region 207-2 of the waveguide 205-2 is separated from region 103 of phase-change material by a distance g2. In this example, distance g2 is equivalent to a thickness of the portion of peripheral region 209 interposed between the central region 207-2 of waveguide 205-2 and region 103 of phase-change material.

Table [Table 1] below provides example of values for height h1, width w1, and distances g1 and g2 according to a width L of region 103 of phase-change material along axis Ox, that is, perpendicularly to the conduction axis Oy of switch 200 and parallel to the propagation direction of the laser signal in optical coupler 201. The width L of region 103 of phase-change material is considered parallel to the propagation direction of the laser signal for controlling switch 200 in optical coupler 201 vertically in line with region 103 (parallel to axis Ox, in the shown example).

TABLE 1

| L (μm) | g1 (nm) | g2 (nm) | h1 (nm) | w1 (nm) |
|---|---|---|---|---|
| 100 | 600 | 300 | 300 | 1,000 |
| 90 | 700 | 400 | 300 | 400 |
| 55 | 600 | 300 | 300 | 400 |
| 45 | 700 | 300 | 200 | 600 |
| 35 | 350 | 75 | 300 | 450 |
| 30 | 400 | 200 | 300 | 600 |

Table [Table 2] below provides, as an example, minimum and maximum values for each dimension h1, w1 of the central regions 207-1 and 207-2 of waveguides 205-1 and 205-2 and for distances g1 and g2, the width L of region 103 of phase-change material being, as a non-limiting example, in the range from 30 to 100 μm.

TABLE 2

| Size or distance | Minimum value | Maximum value |
|---|---|---|
| g1 (nm) | 400 | 700 |
| g2 (nm) | 75 | 400 |
| h1 (nm) | 200 | 300 |
| w1 (nm) | 400 | 1,000 |

The examples given hereabove are however not limiting, and those skilled in the art are capable of defining the values of the dimensions h1 and w1 of the central regions 207-1 and 207-2 of waveguides 205-1 and 205-2 and the values of distances g1 and g2 as a function of the width L of region 103 of phase-change material. Digital simulation tools may be used for this purpose. As an example, distances g1 and g2 and height h1 may be constrained due to thicknesses of the layers of material deposited during the steps of manufacturing of switch 200.

An advantage of the switch 200 discussed hereabove in relation with FIGS. 2A, 2B and 2C lies in the fact that the presence of the optical coupler enables to ensure that the laser signal for controlling switch 200 is substantially uniformly absorbed by the phase-change material of region 103. More specifically, in the case of switch 200, only the transverse magnetic mode TM in upper waveguide 205-1, lightly absorbed, is present close to the input of optical coupler 201 (vertically in line with portion 103N of region 103), while only the transverse magnetic mode TM in lower waveguide 205-2, strongly absorbed, is present close to the output of optical coupler 201 (vertically in line with portion 103F of region 103). This enables to avoid, as compared with the switch 100 of FIGS. 1A and 1B, for a portion of region 103 of phase-change material, for example the portion 103F most distant from laser source LS, not to change phase during the control of the switch.

FIG. 3 is a simplified and partial side view of an example of a transmitarray antenna 400 of the type to which, as an example, described embodiments apply.

Antenna 400 typically comprises one or a plurality of primary sources 401 (a single source 401, in the shown example) irradiating a transmitarray 403. Source 401 may have any polarization, for example linear or circular. Array 403 comprises a plurality of elementary cells 405, for example arranged in a matrix of rows and columns. Each cell 405 typically comprises a first antenna element 405a, located on the side of a first surface of array 403 arranged in front of primary source 401, and a second antenna element 405b, located on the side of a second surface of array 403 opposite to the first surface. The second surface of array 403 for example faces an emission medium of antenna 400.

Each cell 405 is capable, in emission mode, of receiving an electromagnetic radiation on its first antenna element 405a and of re-emitting this radiation from its second antenna element 405b, for example by introducing a known phase shift q. In receive mode, each cell 405 is capable of receiving an electromagnetic radiation on its second antenna element 405b and of re-emitting this radiation from its first antenna element 405a, towards source 401, with the same phase shift q. The radiation re-emitted by the first antenna element 405a is, for example, focused on source 401.

The characteristics of the beam generated by antenna 400, in particular its shape and its maximum transmission direction (or pointing direction), depend on the values of the phase shifts respectively introduced by the various cells 405 of array 403.

Transmitarray antennas have as advantages, among others, of having a good energy efficiency and of being relatively simple, inexpensive and of having a low bulk. This is in particular due to the fact that transmitarrays can be manufactured in planar technology, generally on printed circuit boards.

Reconfigurable transmitarray antennas 403 are here more particularly considered. Transmitarray 403 is said to be reconfigurable when elementary cells 405 are individually electronically controllable to modify their phase shift value φ, which enables to dynamically modify the characteristics of the beam generated by the antenna, and in particular to modify its pointing direction without mechanically displacing the antenna or a portion of the antenna by means of a motor-driven element.

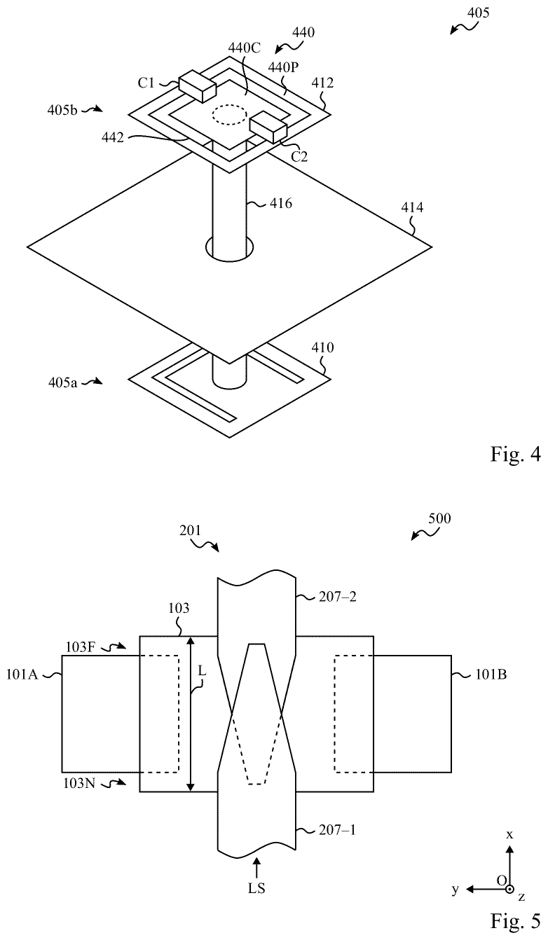

FIG. 4 is a simplified and partial isometric view of one of the elementary cells 405 of the transmitarray 403 of the antenna 400 of FIG. 3 according to an embodiment.

In the shown example, the first antenna element 405a of elementary cell 405 comprises a patch antenna 410 adapted to capturing the electromagnetic radiation emitted by source 401, and the second antenna element 405b comprises another patch antenna 412 adapted to emitting, towards the outside of antenna 400, a phase-shifted signal. In the shown example, elementary cell 405 further comprises a ground plane 414 interposed between patch antennas 410 and 412.

Antenna 410, ground plane 414, and antenna 412 are, for example, respectively formed in three successive metallization levels, stacked and separated from one another by dielectric layers, for example made of quartz. As an example, ground plane 414 is separated from each of the antennas 410 and 412 by a thickness of dielectric material in the order of 200 μm.

In the shown example, a central conductive via 416 connects antenna 410 to antenna 412. More specifically, in the orientation of FIG. 4, via 416 has a lower end in contact with an upper surface of antenna 410 and an upper end in contact with a lower surface of antenna 412. Central conductive via 416 is electrically insulated from ground plane 414. In the shown example, ground plane 414 comprises a circular hole having a diameter larger than that of via 416, thus enabling via 416 to cross ground plane 414 without for via 416 to be in contact with ground plane 414. As an example, central conductive via 416 has a diameter equal to approximately 80 μm.

In the shown example, antenna 412 comprises a four-sided conductive plane 440. Conductive plane 440 for example more precisely has a rectangular shape or, as in the example illustrated in FIG. 4, a substantially square shape.

In the illustrated example, conductive plane 440 comprises an opening 442 separating a central region 440C of conductive plane 440 from a peripheral region 440P of conductive plane 440. In this example, opening 442 is substantially ring-shaped, for example has a rectangular or square ring shape.

In the shown example, central conductive via 416 is in contact with the central region 440C of conductive plane 440. More specifically, in this example, the upper end of via 416 is substantially connected to the center of a lower surface of region 440C. The central region 440C of conductive plane 440, laterally delimited by ring-shaped opening 442, for example forms an input terminal of antenna 412.

Antenna 412 further comprises a first switching element C1 and a second switching element C2, each coupling central region 440C to the peripheral region 440P of conductive plane 440. More specifically, in the example shown in FIG. 4, the first and second switching elements C1 and C2 contact peripheral region 440P in areas diametrically opposite with respect to central conductive via 416. In this example, switching elements C1 and C2 and conductive via 416 are located on a same straight line parallel to one of the sides of conductive plane 440. In this example, switch C1 is located substantially vertically with respect to the horizontal branch of the U formed by slot 442.

Switching elements C1 and C2 are controlled in opposition, that is, so that if one of switches C1, C2 is on, the other switch C2, C1 is off. This enables the second antenna element 405b of elementary cell 405 to switch between two phase states q, substantially equal to 0° and 180° in this example. Phase states 0° and 180° respectively correspond to the case where switch C1 is off while switch C2 is on, and to the case where switch C1 is on while switch C2 is off.

Each switching element C1, C2 of elementary cell 405 is for example formed by the previously-described switch 200. In this case, the fact of using laser source LS to control the switches C1 and C2 of antenna element 405b has the advantage of decreasing the number of electrically-conductive control lines. As compared with switches made of a phase-change material controlled by direct heating, for example by the flowing of a current through the phase-change material, or by indirect heating, for example, by the flowing of a current through a heating element electrically insulated from the phase-change material, for which two control lines are used, one to apply the control potential, the other to apply the reference potential, a single optical control line, for example the upper waveguide 205-1 of the optical coupler of each switch C1, C2, is used to control the switching of each switch C1, C2.

Another advantage of switches C1 and C2 lies in the fact that they have a capacitance C_{off} in the off state lower than that of conventional indirectly-heated switches, which typically comprise a heating element made of an electrically-conductive material, for example a metal, electrically insulated from the phase-change material.

In transmitarray 403, it may for example be provided to use a different laser source LS to control each switch C1, C2 of each second antenna element 405b, the emission of the laser sources LS of the transmitarray 403 being controlled by a control circuit (not shown). Laser source LS is then for example of “integrated” type, that is, it forms part of a same chip as the switch(es) with which it is associated.

As a variant, it may be provided to use a single laser source LS to control a plurality of switches C1, C2 of the second antenna elements 405b of transmitarray 403. In this case, each second antenna element 405b may, for example, be associated with an optical switch for controlling switches C1 and C2 in phase opposition, or with a “1-to-N”-type multiplexer, with N an integer greater than two, adapted to controlling a plurality of switches C1, C2 of a plurality of second antenna elements 405b.

An advantage of switches C1 and C2 based on phase-change material is that they are capable of operating at power levels at least as high as those typically used in elementary cells of reconfigurable transmitarray or reflectarray antennas, while providing a better linearity. Further, switches C1 and C2 provide an excellent stability in frequency ranges in the order of one terahertz.

Further, the transmitarray 403 comprising cells 405 integrating switches C1 and C2 advantageously has a lower power consumption than current transmitarrays for example comprising components such as p-i-n diodes or varactors.

FIG. 5 is a simplified and partial top view illustrating an example of a switch 500 based on a phase-change material according to an embodiment.

The switch 500 of FIG. 5 comprises elements in common with the switch 200 of FIGS. 2A, 2B, and 2C. These common elements will not be detailed again hereafter. The switch 500 of FIG. 5 differs from the switch of FIGS. 2A, 2B, and 2C in that the optical coupler 201 of switch 500 is of “adiabatic” type.

In the shown example, the output surface of upper waveguide 205-1 and the input surface of waveguide 205-2 each have, in top view, a tapered shape. More specifically, in this example, the central region 207-1 of upper waveguide 205-1 is wider vertically in line with portion 103N of region 103 than vertically in line with portion 103F, and the central region 207-2 of lower waveguide 205-2 is wider vertically in line with portion 103F of region 103 than vertically in line with portion 103N. This enables to form, between upper waveguide 205-1 and lower waveguide 205-2, an adiabatic-type coupling.

In the shown example, the propagation axes of the radiation within waveguides 205-1 and 205-2 are substantially parallel to each other, and parallel to axis Ox, waveguides 205-1 and 205-2 each being for example substantially rectilinear.

Various embodiments and variants have been described. Those skilled in the art will understand that certain features of these various embodiments and variants may be combined, and other variants will occur to those skilled in the art. In particular, the geometry and the dimensions of central regions 207-1 and 207-2 of waveguides 205-1 and 205-2 may be adapted by those skilled in the art based on the indications of the present disclosure, for example as a function of the targeted application. As an example, the central region 207-2 of lower waveguide 205-2 could begin vertically in line with portion 103N of region 103 of phase-change material and/or end vertically in line with portion 103F of region 103.

Further, although an example of an elementary cell 405 comprising two switches of phase-change material C1 and C2 has been described, the described methods can be transposed by those skilled in the art to any number of switches made of phase-change material. As an example, a number of switches made of phase-change material greater than two could be provided in a case where a reconfigurable elementary cell having more than two different phase states would be desired to be formed.

Further, although only an example of application to transmitarray antennas has been described hereabove, the optically-controlled switch made of phase-change material described in relation with FIGS. 2A, 2B, and 2C may have other applications. More generally, such a switch may be used in any application capable of taking advantage of a decrease in the number of electric connection tracks to control a switch. As an example, such a switch may be integrated to reflectarray antennas, filters, phase-shifter circuits, etc. and, more generally, to any type of application using a switch.

In particular, the transposition of the described embodiments to the case of a reflectarray antenna is within the abilities of those skilled in the art based on the indications of the present disclosure.

Further, those skilled in the art are capable, based on the indications of the present disclosure, of providing for each of the phase-change switches C1 and C2 of the elementary cell 405 to be identical or similar to the switch 500 of FIG. 5.

Finally, the practical implementation of the described embodiments and variants is within the abilities of those skilled in the art based on the functional indications given hereabove. In particular, the described embodiments are not limited to the specific examples of materials and dimensions mentioned in the present disclosure. Further, the embodiments are not limited to the example of geometry of patch antennas 410 and 412 described in relation with FIG. 4, but more generally apply to any type of antenna geometry.

What is claimed is:

1. Switch based on a phase-change material comprising:
a region made of said phase-change material coupling first and second conduction electrodes of the switch; and
an optical coupler of a laser signal for activating the switch, located in front of a surface of the region made of said phase-change material,
wherein the optical coupler comprises first and second waveguides stacked in front of said surface, the second waveguide being interposed between the first waveguide and the region made of said phase-change material.

2. Switch according to claim 1, wherein the first and second waveguides each comprise a central region made of a first material surrounded by a peripheral region made of a second material having an optical index lower than that of the first material.

3. Switch according to claim 2, wherein the central regions of the first and second waveguides are stacked, in front of each other and have a same pattern vertically in line with the region made of said phase-change material.

4. Switch according to claim 2, wherein the central regions of the first and second waveguides do not have a same pattern out of line with the region made of said phase-change material.

5. Switch according to claim 2, wherein the central region of the first waveguide has a geometry and dimensions substantially identical to those of the central region of the second waveguide.

6. Switch according to claim 1, wherein the optical coupler is an adiabatic coupler.

7. Switch according to claim 6, wherein the first and second waveguides respectively comprise output and input surfaces, each having, in top view, a tapered shape.

8. Switch according to claim 1, wherein the laser signal is confined and guided mainly by the first waveguide, at the input of the optical coupler, and mainly by the second waveguide, at the output of the optical coupler.

9. Switch according to claim 1, wherein the first and second conduction electrodes form part of an antenna element of a cell of a transmitarray or of a reflectarray.

10. Cell of a transmitarray or of a reflectarray comprising at least one switch according to claim 1.

11. Transmitarray or reflectarray comprising:
a plurality of cells according to claim 10;
one or a plurality of laser sources; and
a circuit for controlling the laser source(s).

12. Array according to claim 11, wherein each laser source forms part of a same chip as each switch with which it is associated.

13. Antenna comprising a transmitarray or a reflectarray according to claim 11 and at least one source configured to irradiate a surface of the array.
